(19) United States
(12) Patent Application Publication
(10) Pub. No.: US 2011/0264293 A1
(43) Pub. Date: Oct. 27, 2011

(54) SYSTEM AND METHOD OF DETERMINING AN ENERGY HARVESTING CAPABILITY OF A LOCATION

(76) Inventors: Earl David Forrest, Asheboro, NC (US); David M. Burke, Taylor, MI (US)

(21) Appl. No.: 12/767,877

(22) Filed: Apr. 27, 2010

(51) Int. Cl. G06F 1/28; G01R 21/00

(52) U.S. Cl. 700/295; 702/60

(57) ABSTRACT

A method of determining an energy harvesting capability of a location harvests energy at a location using an energy harvester and charges an energy storage device using the harvested energy. The energy storage device is discharged into a test circuit to provide a notification. The steps of charging the energy storage device and discharging the energy storage device are selectively repeated such that the notification is provided at a rate proportional to an amount of energy being harvested at the location.

### BACKGROUND

This application relates to energy harvesting, and more particularly to a system and method for determining an energy harvesting capability of a location.

Solar cells have been used to harvest power for various loads. Solar cells require adequate levels of light in order to harvest sufficient amounts of energy to power their respective loads. Determining acceptable locations for solar cells has involved using expensive equipment such as a lux meter.

### SUMMARY

In one embodiment, a method of determining an energy harvesting capability of a location harvests energy at a location using an energy harvester and charges an energy storage device using the harvested energy. The energy storage device is discharged into a test circuit to provide a notification. The steps of charging the energy storage device and discharging the energy storage device are selectively repeated such that the notification is provided at a rate proportional to an amount of energy being harvested at the location.

In one embodiment, a circuit for determining an energy harvesting capability of a location includes an energy harvester operable to harvest energy from environmental conditions at a location and a notification device operable to provide a notification at a rate proportional to an amount of energy being harvested by the energy harvester at the location.

In one embodiment, a method of determining an energy harvesting capability of a location connects an energy harvester to a first energy storage device in a test mode. A system load is not powered in the test mode. The first energy storage device is charged using energy harvested by the energy harvester at a location. A charge of the first energy storage device is compared to a desired charge, and a notification is provided to indicate the result of the comparison. The first energy storage device is disconnected from the energy harvester and the energy harvester is connected to a second energy storage device in an operational mode in response to the capacitor charge being greater than or equal to a desired charge. The second energy storage device has a greater energy storage capacity than the first storage device, and in the operational mode the system load is powered by the energy harvester via the second energy storage device.

In one embodiment, a circuit for determining an energy harvesting capability of a location includes an energy harvester operable to harvest energy from environmental conditions, a first energy storage device being charged by the energy storage device in a test mode, and a second energy storage device being charged by the energy storage device in an operational mode. The second energy storage device has an energy storage capacity that is greater than an energy storage capacity of the first energy storage device. The circuit also includes at least one notification device operable to provide a notification if a charge of the first energy storage device is greater than or equal to a desired charge. A system load is powered by the energy harvester via the second energy storage device in the operational mode, and is not powered in the test mode. A switch is operable to change between the test mode and the operational mode by connecting or disconnecting the energy storage devices from the energy harvester.

These and other features of the present invention can be best understood from the following specification and drawings, the following of which is a brief description.

### BRIEF DESCRIPTION OF THE DRAWINGS

FIG. 1 schematically illustrates a first circuit for determining an energy harvesting capability of a location.

FIGS. 2-5 schematically illustrate various portions of another circuit for determining an energy harvesting capability of a location.

### DETAILED DESCRIPTION

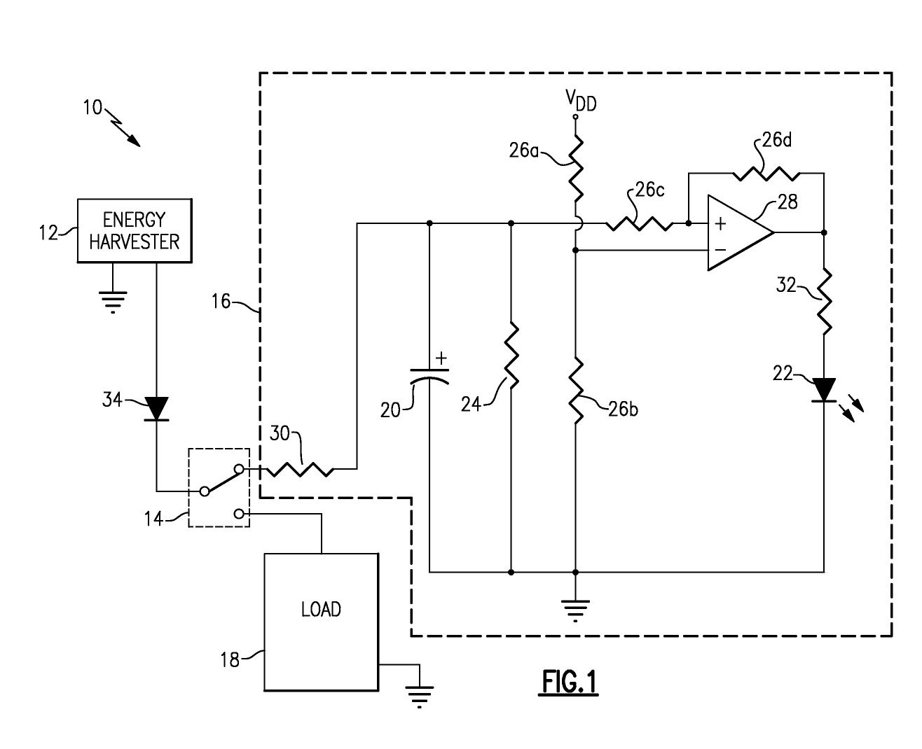

FIG. 1 schematically illustrates a circuit 10 for determining an energy harvesting capability of a location to determine an optimal placement for an energy harvester 12 at that location. The energy harvester 12 is operable to harvest energy from environmental conditions at the location. The energy harvester may include one or more photovoltaic cells operable to harvest solar energy, for example.

A switch 14 is operable to command the circuit to switch between powering a test portion 16 of the circuit 10 (in a “test mode”) and powering a load 18 of the circuit 10 (in an “operational mode”). If the test portion 16 indicates that a sufficient amount of energy is being harvested at the location, the switch 14 may cause the circuit 10 to enter the operational mode such that the energy harvester 12 powers the load 18.

An energy storage device 20 repeatedly charges from the energy harvester 12 and discharges to power a notification device 22 such that the notification device 22 provides notifications at a rate proportional to an amount of energy being harvested by the energy harvester 12 at the location. In one example the energy storage device 20 includes a capacitor and the notification device 22 includes a light-emitting diode (“LED”). Of course, other energy storage and notification devices could be used.

A resistor 24 connected in parallel to the energy storage device 20 is used to simulate an energy demand of the load 18. A plurality of additional resistors 26a-d are connected to each other (with resistors 26a-b connected in series and resistors 26c-d connected in series), and are collectively connected to comparator 28 to exhibit a hysteresis effect such that the resistors 26a-d and comparator 28 establish a voltage threshold required to turn the comparator output ON. Thus, once the charge of the energy storage device 20 reaches a level sufficient to meet or exceed the voltage threshold, the comparator 28 turns ON and the energy storage device 20 discharges to power the notification device 22. The energy storage device then repeatedly charges and discharges such that the notification device 22 provides a notification at a rate proportional to an amount of energy being harvested by the energy harvester 12 at the location. Optional current limiting resistors 30, 32 may be used to control an amount of current that flows through the test portion 16 of the circuit 10. A diode 34 prevents backcharging from the energy storage device 20 back into the energy harvester 12.

The notification rate of the notification device 22 is compared to a desired notification rate that represents an amount of energy being sufficient to power the load 18. If the notification rate is less than the desired notification rate, the energy harvester 12 or the entire circuit 10 may be moved to another location to determine whether the other location enables the energy harvester 12 to harvest more energy. If the notification rate is greater than or equal to the desired notification rate the switch 14 may be used to command the circuit 10 to enter the operational mode such that the load 18 is powered by the energy harvester 12 and the test portion 16 of the circuit 10 is disconnected from the energy harvester 12.

A technician could use the circuit 10 to determine where to place a solar panel. If the notification rate was too low the technician would know that an insufficient amount of light would be available to power a load of the solar panel, and if the rate was high enough the technician would know that the solar panel location was acceptable. Thus, the technician could avoid the use of complicated and expensive tools such as lux meters in determining an optimal solar panel location.

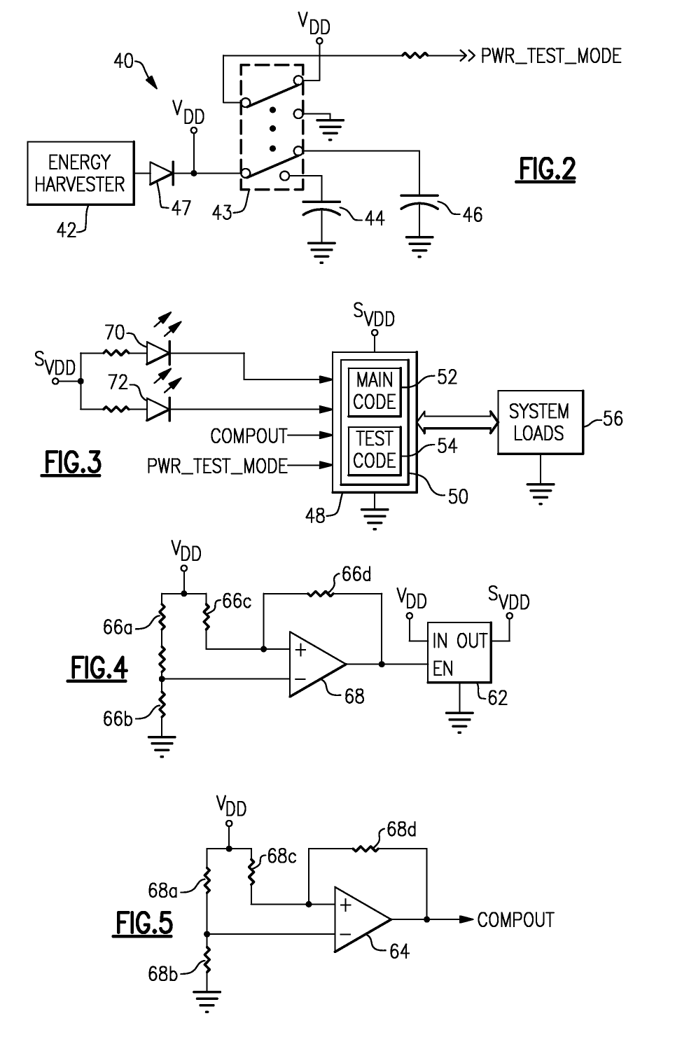

FIGS. 2-5 schematically illustrate various portions of another circuit 40 for determining an energy harvesting capability of a location. Referring to FIG. 2, the circuit 40 includes an energy harvester 42 and a switch 43 operable to connect the energy harvester 42 to one of a first energy storage device 44 (in a “test mode”) or a second energy storage device 46 (in an “operational mode”), with the second energy storage device 46 having a greater energy storage capacity than the first energy storage device 44. In one example, the energy storage devices 44, 46 include capacitors. Of course, other energy storage devices could be used. The switch 43 may be a double pole, double throw (“DPDT”) switch that has six terminals and controls two separate flows of current. A diode 47 prevents the energy storage devices 44, 46 from backcharging into the energy harvester 42.

Referring to FIG. 3, a microcontroller 48 has memory 50 that stores both main code 52 and test code 54. In the operational mode the energy storage device 46 is connected to the energy harvester 42, and the signal PWR_TEST_MODE is pulled high, commanding the microcontroller 48 to execute the main code 52. In one example the main code involves powering system loads 56, which may include one or more motion sensors, for example.

In the test mode the energy storage device 44 is connected to the energy harvester 42, and the signal PWR_TEST_MODE is pulled low, commanding the microcontroller 48 to execute the test code 54. In one example the test code 54 prevents the microcontroller from powering the system loads 56.

The signal COMPOUT is used to indicate if the energy harvester 42 is harvesting a sufficient amount of energy to power both the microcontroller 48 and the system loads 56. The COMPOUT signal is determined using comparator 60, regulator 62, and comparator 64 (see FIGS. 4-5).

Referring to FIG. 4, the comparator 60 is used to determine if the energy harvester 42 is harvesting a sufficient amount of energy to power the microcontroller 50. A first plurality of resistors 66a-d are configured to exhibit a hysteresis effect such that the resistors 66a-d and comparator 60 collectively establish a first voltage threshold required to turn ON the output of comparator 60. A voltage V_{DD} is connected to the output of the energy harvester 42. If the comparator 60 is turned ON, regulator 62 regulates the voltage V_{DD} to provide a regulated system voltage S_{VDD}.

Referring to FIG. 5, the comparator 64 is used to determine if the energy harvester 42 is harvesting a sufficient amount of energy to power both the microcontroller 50 and the system loads 56. A second plurality of resistors 68a-d are configured to exhibit a hysteresis effect such that the resistors 68a-d and comparator 64 collectively establish a second voltage threshold required to turn ON the output of comparator 64. In one example the second voltage threshold (of resistors 68a-d and comparator 64) is greater than the first voltage threshold (of resistors 66a-d and comparator 60). If the energy storage device 44 has a charge that is greater than or equal to the second voltage threshold, the comparator 64 output turns ON such that the COMPOUT signal is ON.

The LEDs 70, 72 act as notification devices to indicate an amount of energy being harvested by energy harvester 42. The COMPOUT signal is OFF by default, causing the microcontroller 50 to turn LED 70 ON. However, if the comparator 64 is turned ON, the COMPOUT signal is turned ON, which commands the microcontroller 50 to turn LED 70 OFF and to turn LED 72 ON, indicating that the energy harvester 42 is harvesting a sufficient amount of energy to power both the microcontroller 50 and the system loads 56. In one example the LED 70 emits red light and the LED 72 emits green light. Of course, other LEDs and other notification devices could be used.

In one example a first notification could be provided to indicate that the energy harvester 42 was harvesting enough energy to power only the microcontroller 48, and a second notification could be provided to indicate that the energy harvester 42 was harvesting enough energy to power both the microcontroller 48 and the system loads 56. The first and second notifications could include turning ON one or both of the LEDs 70, 72, or could include flashing one or both of the LEDs 70, 72 ON/OFF at a certain rate, for example.

Thus, as with the circuit 10 of FIG. 1, a technician could use the circuit 40 to determine where to place a solar panel. If the LED 70 was emitting light, the technician would know that an insufficient amount of light would be available to power a load of the solar panel, and if the LED 72 was emitting light the technician would know that the solar panel location was acceptable, and the technician could cause switch 43 change from the test mode to the operational mode. Thus, the technician could avoid the use of complicated and expensive tools such as lux meters in determining an optimal solar panel location.

Although multiple embodiments have been disclosed, a worker of ordinary skill in this art would recognize that certain modifications would come within the scope of this invention. For that reason, the following claims should be studied to determine the true scope and content of this invention.

What is claimed is:

1. A method of determining an energy harvesting capability of a location, comprising:
harvesting energy at a location using an energy harvester;
charging an energy storage device using the harvested energy;
discharging the energy storage device into a test circuit to provide a notification; and
selectively repeating said steps of charging the energy storage device and discharging the energy storage device such that the notification is provided at a rate proportional to an amount of energy being harvested at the location.

2. The method of claim 1, including:
comparing the notification rate to a desired notification rate, the desired notification rate indicating an amount of energy being harvested that is sufficient to power a selected load; and
moving the energy harvester to another location and in response to the notification rate being less than a desired notification rate.

3. The method of claim 1, including:
comparing the notification rate to a desired notification rate, the desired notification rate indicating an amount of energy being harvested that is sufficient to power a selected load; and
disconnecting the energy storage device from the test circuit and connecting the energy harvester to the load in response to the notification rate being greater than or equal to a desired notification rate.

4. The method of claim 1, wherein said step of harvesting energy at a location using an energy harvester includes using at least one photovoltaic cell to harvest solar energy, and wherein the energy storage device includes at least one capacitor.

5. The method of claim 1, wherein said step of discharging the energy storage device to provide a notification includes:
connecting the energy storage device to a plurality of resistors configured to exhibit a hysteresis effect voltage threshold; and
connecting the energy storage device and the plurality of resistors to a comparator; and
turning ON the comparator output to pass current through a notification device to provide the notification in response to a charge of the energy storage device exceeding the hysteresis effect voltage threshold.

6. The method of claim 5, wherein the notification device includes at least one light-emitting diode.

7. A circuit for determining an energy harvesting capability of a location, comprising:
an energy harvester operable to harvest energy from environmental conditions at a location; and
a notification device operable to provide a notification at a rate proportional to an amount of energy being harvested by the energy harvester at the location.

8. The circuit of claim 7, including:
an energy storage device connected to the energy harvester and operable to be charged by the energy harvester;
a plurality of resistors connected to the energy storage device and configured to exhibit a hysteresis effect voltage threshold; and
a comparator operable to turn ON to provide current to the notification device in response to a charge of the energy storage device exceeding the hysteresis effect voltage threshold.

9. The circuit of claim 8, including:
a load, wherein the energy harvester is connected to the energy storage device in a first, test mode, and wherein the energy harvester is disconnected from the energy storage device and is connected to the load in a second, operational mode in response to the notification rate being greater than or equal to a desired notification rate.

10. The circuit of claim 7, wherein the energy harvester includes at least one photovoltaic cell operable to harvest solar energy.

11. A method of determining an energy harvesting capability of a location, comprising:
connecting an energy harvester to a first energy storage device in a test mode, a system load not being powered in the test mode;
charging the first energy storage device using energy harvested by the energy harvester at a location;
comparing a charge of the first energy storage device to a desired charge;
providing a notification to indicate the result of the comparison; and
disconnecting the first energy storage device from the energy harvester and connecting the energy harvester to a second energy storage device in an operational mode in response to the capacitor charge being greater than or equal to a desired charge, wherein the second energy storage device has a greater energy storage capacity than the first storage device, and wherein in the operational mode the system load is powered by the energy harvester via the second energy storage device.

12. The method of claim 11, including:
A) relocating the energy harvester to another location in response to the notification indicating that capacitor charge rate is less than the desired charge;
B) repeating said steps of charging the first energy storage device using energy harvested by the energy harvester and comparing a charge of the first energy storage device to a desired charge; and
C) selectively repeating steps (A)-(B) until the notification indicates that the capacitor charge is greater than or equal to the desired charge.

13. The method of claim 11, wherein said providing a notification to indicate the result of the comparison includes:
illuminating at least one first light-emitting diode having a first color in response to the capacitor charge being greater than or equal to the desired charge; and
illuminating at least one second light-emitting diode having a second color different from the first color in response to the capacitor charge being less than the desired charge.

14. The method of claim 11, wherein said providing a notification to indicate the result of the comparison includes:
providing a notification at a rate proportional to an amount of energy being harvested at the location.

15. The method of claim 11, wherein said step of charging the first energy storage device using energy harvested by the energy harvester at a location includes using at least one photovoltaic cell to harvest solar energy.

16. A circuit for determining an energy harvesting capability of a location, comprising:
an energy harvester operable to harvest energy from environmental conditions;
a first energy storage device being charged by the energy storage device in a test mode;
a second energy storage device being charged by the energy storage device in an operational mode, the second energy storage device having an energy storage capacity that is greater than an energy storage capacity of the first energy storage device;
at least one notification device operable to provide a notification if a charge of the first energy storage device is greater than or equal to a desired charge;
a system load being powered by the energy harvester via the second energy storage device in the operational mode, and not being powered in the test mode; and
a switch operable to change between the test mode and the operational mode by connecting or disconnecting the energy storage devices from the energy harvester.

17. The circuit of claim 16, including:
at least one comparator; and
at least one plurality of resistors configured to exhibit a hysteresis effect, wherein the at least one comparator and the at least one plurality of resistors compare the charge of the first energy storage device to the desired charge, and turn ON a comparator output to command the at least one notification device to provide the notification in response to the capacitor charge being greater than or equal to the desired charge.

18. The circuit of claim 16, wherein each of the first and second energy storage devices includes at least one capacitor.

19. The circuit of claim 16, wherein the notification device includes at least one light-emitting diode operable to provide a first notification if a charge of the first energy storage device is less than a desired charge, and operable to provide a second notification if a charge of the first energy storage device is greater than or equal to the desired charge.

20. The circuit of claim 16, including a microcontroller operable to control the notification device, wherein the microcontroller is operable to command the notification device to provide a first notification if a charge of the first energy storage device is sufficient to power only the microcontroller, and wherein the microcontroller is operable to command the notification device to provide a second notification if a charge of the first energy storage device is sufficient to power both the microcontroller and the system load.
